(19) United States
(12) Patent Application Publication
(10) Pub. No.: US 2011/0101307 A1
(43) Pub. Date: May 5, 2011

(54) SUBSTRATE FOR SEMICONDUCTOR DEVICE AND METHOD FOR MANUFACTURING THE SAME

(75) Inventors: Hae Yong LEE, Yongin-Si (KR); Young Jun CHOI, Seoul (KR); Jung Gyu KIM, Busan (KR); Hyun Hee HWANG, Busan (KR)

(73) Assignee: LUMIGNTECH CO., LTD., Seoul (KR)

(21) Appl. No.: 12/917,970

(22) Filed: Nov. 2, 2010

(30) Foreign Application Priority Data
Nov. 3, 2009 (KR) 10-2009-0105515

(51) Int. Cl. H01L 29/15; H01L 21/306

(52) U.S. Cl. 257/22; 438/479; 257/E29.072; 257/E21.23

(57) ABSTRACT

Provided are a semiconductor substrate including an uneven structure disposed on a surface of a substrate, a buffer layer disposed on the uneven structure, the buffer layer having an acicular structure, a compound semiconductor layer disposed on the buffer layer to planarize the uneven structure, and a plurality of voids defined between the substrate and the compound semiconductor layer, and a method for manufacturing the same. Thus, since the acicular structure disposed on the uneven structure of the substrate forms the voids on an interface between the substrate and the single crystal GaN layer to relax a stress due to a lattice mismatch and intercept propagation of a breakdown potential, a warpage characteristic of the grown single crystal GaN layer may be reduced, as well as, crystallinity may be improved.

### CROSS-REFERENCE TO RELATED APPLICATION

This application claims priority to Korean Patent Application No. 10-2009-0105515 filed on Nov. 3, 2009 and all the benefits accruing therefrom under 35 U.S.C. §119, the contents of which are incorporated by reference in their entirety.

### BACKGROUND

The present disclosure relates to a substrate for a semiconductor device and a method for manufacturing the same, and more particularly, to a semiconductor substrate including a GaN layer, which is used as a substrate when various power devices are manufactured, and a method for manufacturing the same.

A semiconductor device is one of electronic components, in which electronic devices such as a power device, a light emitting device, and a light receiving device are mounted on a predetermined substrate using a semiconductor process technology. For example, a transistor, a metal-oxide-semiconductor field-effect transistor (MOSFET), an insulated gate bipolar transistor (IGBT), and a schottky diode may be mounted on a substrate to realize the power device. Also, a solar cell and a photo sensor may be mounted on a substrate to realize the light receiving device.

Particularly, a semiconductor light emitting device using GaN may emit blue light. Thus, since the blue light emitting device using GaN-based compound semiconductor together with existing green and red light emitting devices using GaAs- and InP-based compound semiconductors may realize a full color effect, the semiconductor light emitting device using the GaN-based compound semiconductor is in the spotlight as light sources of various displays.

However, for growing a high-quality GaN thin film, a high-quality GaN single crystal substrate having the same lattice constant and thermal expansion coefficient is needed. Since GaN has a melting point of approximately 2400° C. and group V nitrogen has a tension greater than those of group III elements, nitrogen should have a pressure of approximately 40,000 atmosphere to grow a single crystal substrate. It is difficult to grow the GaN single crystal using the current Si, GaAs, or InP single crystal growth technology.

Thus, a hetero-substrate such as sapphire (α-Al2O3) having significant mismatch with GaN in the lattice constant and the thermal expansion coefficient is used in recent years. Also, the blue light emitting device using GaN may be manufactured through a hereroepitaxy in which a GaN epitaxial layer is grown using an AlN or GaN buffer layer to relax the mismatch between sapphire and GaN.

However, in case of the sapphire substrate, since the single GaN layer and the sapphire substrate have cleavage directions different from each other, it is difficult to manufacture a resonator having a superior property. In addition, unlike silicon, it is difficult to split an assembly of the single crystal GaN and the sapphire. Also, when the single crystal GaN is grown on the hetero-substrate, a GaN nano-rod or an AlN buffer layer must be used at a low-temperature of approximately 500° C. to approximately 600° C. to relax the mismatch between the substrate and the single crystal GaN. Thus, there are limitations that an epitaxial growth process becomes complicated and the temperature should be increased again to perform a thick film growth. In addition, it is difficult to grow various compounds such as InN and GaN, which are required for growth of a device structure.

Particularly, since the single crystal GaN layer grown on the sapphire substrate has a very high dislocation density (10⁸ cm⁻² to 10⁹ cm⁻²) due to differences of the lattice constant and the thermal expansion coefficient therebetween, performance of the manufactured power device is not superior. Also, when the GaN layer has a thickness greater than a predetermined thickness (greater than approximately 7 μm), warpage of magnitude greater than approximately 70 μm may occur. Thus, it is difficult to perform a subsequent process for manufacturing the device, i.e., a substrate alignment process, a photo process, and an etching process.

As describe above, it is difficult to perform the subsequent process due to the dislocation density and warpage occurring by the differences of the lattice constant and the thermal expansion coefficient between the sapphire substrate and the grown single crystal GaN layer.

### SUMMARY

The present disclosure provides a semiconductor substrate, which can be utilized for manufacturing a high-performance semiconductor device having superior surface characteristics and crystallinity and a method for manufacturing the same.

The present disclosure also provides a semiconductor substrate in which a less warpage phenomenon of the substrate occurs in a state where the substrate is applied to a subsequent semiconductor device process even though a device layer has relatively thick thickness to easily perform a subsequent device manufacturing process and minimize product defects or proportion defective, and a method for manufacturing the same.

In accordance with an exemplary embodiment, a semiconductor substrate includes: an uneven structure formed on a surface of a substrate; a buffer layer disposed on the uneven structure, the buffer layer having an acicular structure; a compound semiconductor layer disposed on the buffer layer to planarize the uneven structure; and a plurality of voids defined between the substrate and the compound semiconductor layer.

The uneven structure may have a surface roughness of approximately 10 Å to approximately 300 Å, and more preferably approximately 14 Å to approximately 110 Å.

The voids may be defined between a concave portion of the uneven structure and the compound semiconductor layer.

The concave portion may have a shape corresponding to a crystal shape of the substrate.

The substrate may include one of a sapphire substrate, a silicon carbide substrate, an aluminum nitride substrate, and a zinc oxide substrate.

The compound semiconductor layer may be formed of one of GaN, AlN, InN, AlGaN, and InGaN.

In accordance with another exemplary embodiment, a method for manufacturing a semiconductor substrate includes: etching a substrate surface to form an uneven structure having a shape corresponding to a crystal shape of the substrate; forming a buffer layer having an acicular structure on the uneven structure; and forming a compound semiconductor layer on the buffer layer to planarize the uneven structure.

The etching of the substrate surface may include increasing a pH value of slurry in a chemical mechanical polishing (CMP) process for polishing the substrate surface.

The etching of the substrate surface may include introducing HCl gas in a state where the substrate is heated.

The etching of the substrate surface may include immersing the substrate in KOH molten salt.

The forming of the buffer layer may include: nitriding the substrate to form the buffer layer on the substrate; and removing weak portions of the buffer layer by etching. And the above described steps may be performed repeatedly.

The substrate may include one of a sapphire substrate, a silicon carbide substrate, an aluminum nitride substrate, and a zinc oxide substrate.

The compound semiconductor layer may be formed of one of GaN, AlN, InN, AlGaN, and InGaN.

### BRIEF DESCRIPTION OF THE DRAWINGS

Exemplary embodiments can be understood in more detail from the following description taken in conjunction with the accompanying drawings, in which:

FIG. 1 is a flowchart illustrating a process for manufacturing a semiconductor substrate in accordance with an exemplary embodiment;

FIGS. 2 to 8 are sectional views explaining a process for manufacturing a semiconductor substrate in accordance with an exemplary embodiment;

FIG. 9 is an atomic force microscope photograph of a single crystal GaN layer in accordance with a comparative example;

FIG. 10 is an atomic force microscope photograph of a single crystal GaN layer in accordance with an experimental example;

FIG. 11 is a rocking curve graph illustrating a (002) plane of the single crystal GaN layer in accordance with a comparative example;

FIG. 12 is a rocking curve graph illustrating a (002) plane of the single crystal GaN layer in accordance with an experimental example;

FIG. 13 is a rocking curve graph illustrating a (102) plane of the single crystal GaN layer in accordance with a comparative example;

FIG. 14 is a rocking curve graph illustrating a (102) plane of the single crystal GaN layer in accordance with an experimental example;

FIG. 15 is a graph illustrating warpage characteristics of a semiconductor substrate including the single crystal GaN layer in accordance with a comparative example;

FIG. 16 is a graph illustrating warpage characteristics of a semiconductor substrate including the single crystal GaN layer in accordance with an experimental example; and

FIG. 17 is a sectional view of a semiconductor device including a semiconductor substrate in accordance with an exemplary embodiment.

### DETAILED DESCRIPTION OF EMBODIMENTS

Hereinafter, specific embodiments will be described in detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art.

In the figures, the dimensions of layers and regions are exaggerated for clarity of illustration. Like reference numerals refer to like elements throughout. It will also be understood that when a layer, a film, a region or a plate is referred to as being ‘on’ another one, it can be directly on the other one, or one or more intervening layers, films, regions or plates may also be present. Further, it will be understood that when a layer, a film, a region or a plate is referred to as being ‘under’ another one, it can be directly under the other one, and one or more intervening layers, films, regions or plates may also be present. In addition, it will also be understood that when a layer, a film, a region or a plate is referred to as being ‘between’ two layers, films, regions or plates, it can be the only layer, film, region or plate between the two layers, films, regions or plates, or one or more intervening layers, films, regions or plates may also be present.

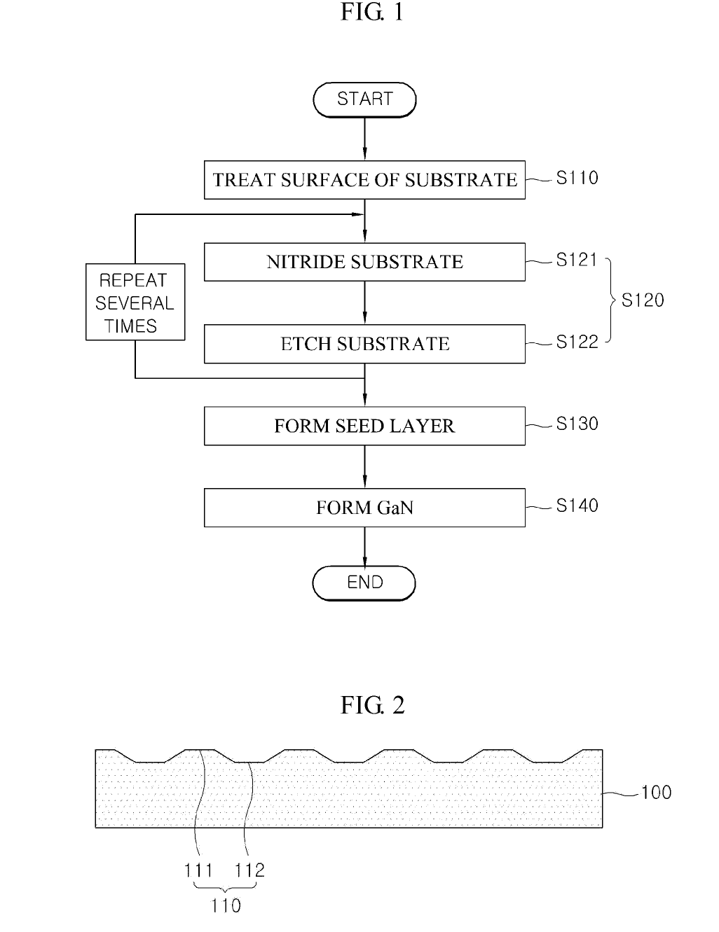

FIG. 1 is a flowchart illustrating a process for manufacturing a semiconductor substrate in accordance with an exemplary embodiment. FIGS. 2 to 8 are sectional views explaining a process for manufacturing a semiconductor substrate in accordance with an exemplary embodiment.

Referring to FIGS. 1 to 8, a surface of a substrate prepared in a substrate surface processing process (S110) is etched to form an unevenness structure including a concave portion having a shape corresponding to a crystal shape of the substrate and a convex portion protruding in a shape corresponding to that of the concave portion. Here, the substrate may include one of a sapphire substrate, a silicon carbide (SiC) substrate, an aluminum nitride (AlN) substrate, and a zinc oxide (ZnO) substrate.

In the current embodiment, a case in which the sapphire substrate is used as the substrate will be described as an example. Referring to FIG. 2, since the sapphire substrate 100 has a hexagonal type crystal shape, an unevenness structure 110 having a concave portion 112 having a hexagonal shape and a convex portion 111 protruding in a shape corresponding to that of the convex portion 111 is formed on a surface of the sapphire substrate 110 through a surface processing process.

Here, a pH value of chemical mechanical polishing (CMP) slurry may be increased in a CMP process for polishing the surface of the sapphire substrate 100 to each the substrate surface, the substrate surface may be etched while HCl gas flows into a furnace having a temperature of approximately 900° C. to approximately 1,100° C. for several seconds to several minutes, for example, approximately 10 minutes to approximately 20 minutes, or the substrate is immersed in KOH molten salt having a temperature of approximately 400° C. to approximately 550° C. for several minutes, for example, approximately 5 minutes to approximately 10 minutes to each the substrate surface, thereby forming the unevenness structure 110.

Thus, the unevenness structure 110 having a surface roughness Ra of approximately 10 Å to approximately 300 Å, particularly, approximately 14 Å to approximately 110 Å may be formed on the surface of the sapphire substrate 100. Here, when the unevenness structure 110 has a surface roughness Ra of less than approximately 10 Å, it may be difficult to form a plurality of voids (see reference numeral 150 of FIG. 7) intended in an exemplary embodiment. However, when the unevenness structure has a surface roughness Ra of greater than approximately 300 Å, it may be difficult to form the plurality of voids as well as perform a surface planarization process. As a result, the surface roughness Ra of a final substrate may be deteriorated. On the other hand, since a separate etching process is not performed on a general sapphire substrate, a soft mirror surface state having a surface roughness Ra of less than approximately 3 Å may be maintained.

Sequentially, in a buffer layer formation process (S120), a nitriding process (S121) and an etching process (S122) are repeatedly performed on the substrate surface to form a buffer layer having an acicular structure on the unevenness structure 110 of the substrate surface. Here, the buffer layer may be formed using various materials. In the current embodiment, a buffer layer formed of AlN having a low lattice parameter difference with respect to a single crystal GaN layer to be formed in a subsequent process will be described as an example. For this, nitrogen gas is supplied under ammonia atmosphere to nitridize the surface of the sapphire substrate 100 (S121), and then, HCl is supplied to etch a weak portion of the nitrided nitride layer, thereby remove the weak portion (S122). Thereafter, the supply of HCl is interrupted (or decreasing the supply amount of HCl) to nitride again the surface of the sapphire substrate 100. Then, HCl is supplied again to etch a weak portion of the nitrided nitride layer, thereby the weak portion.

Referring to FIG. 3, when the nitriding process (S121) and the etching process (S122) are repeatedly performed several times, since a growth rate of the buffer layer 120 on the weak portion of the layer is slower than that of the buffer layer 120 on a strong portion of the layer, the buffer layer 120 may have an acicular structure. Also, since the sapphire substrate is used in the current embodiment, Al of the sapphire substrate 100 and N of the nitrogen gas react with each other to form an AlN buffer layer 120 on the sapphire substrate 100. The AlN buffer layer 120 may prevent cracks due to the lattice mismatch generated when the single crystal GaN layer is grown in the successive process from occurring. In addition, the AlN butter layer 120 has the acicular structure to spatially restrict the growth of the single crystal GaN layer on the uneven concave portion 112 of the sapphire substrate 110, thereby forming the plurality of voids on the uneven concave portion 112 of the sapphire substrate 110.

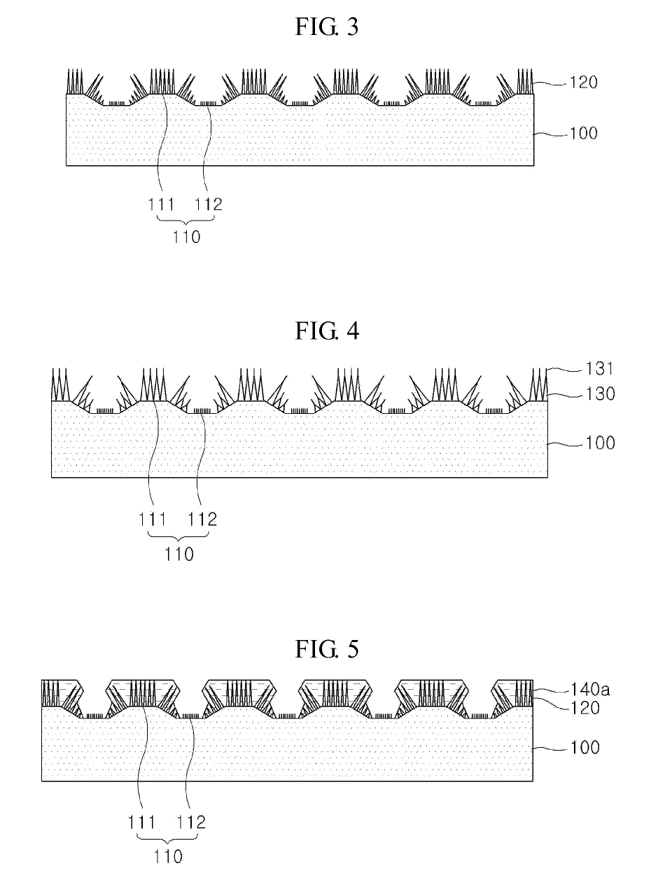

Sequentially, in a seed layer formation process (S130), mixed gas mixing the HCl gas with the nitrogen gas and mixed gas mixing the ammonia gas with the nitrogen gas respectively flows to allow GaN generated by reacting GaCl gas generated by reacting a gallium metal with the HCl gas with N atoms thermally decomposed by the ammonia gas to be grown on the surface of the sapphire substrate 110 on which the AlN buffer layer 120 is formed. Thus, as shown in FIG. 4, the AlN buffer layer 120 having the acicular structure is grown in a rough cone shape to form a seed layer. Also, a nano-rod 131 is formed on a cone end of the seed layer 130.

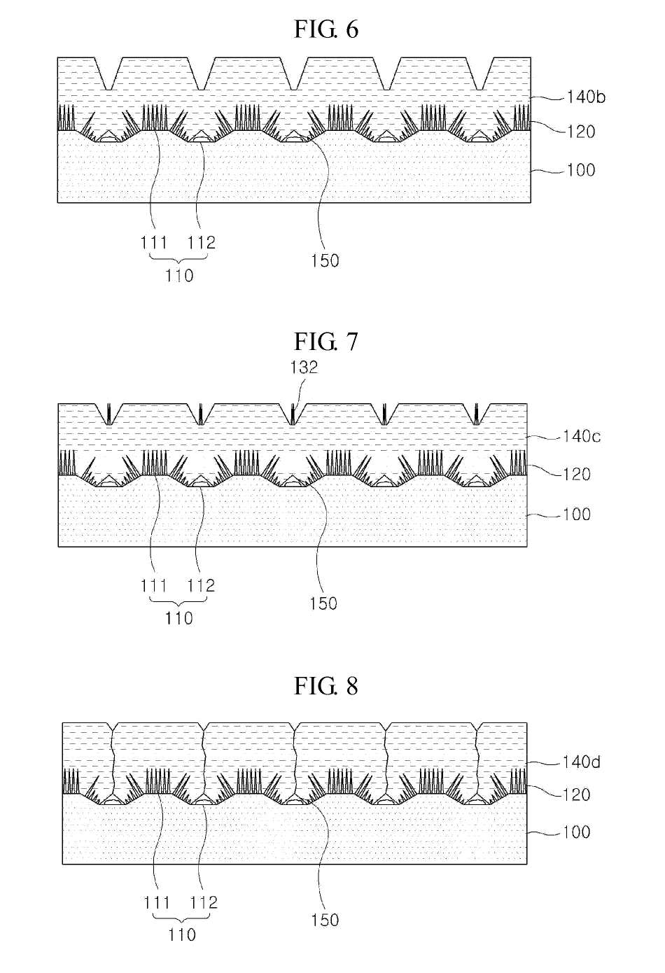

Thereafter, in a GaN layer formation process (S140), the single crystal GaN layer 140a or 140d is grown with a predetermined thickness around the seed layer 130 on the sapphire substrate 100 to planarize the surface of the sapphire substrate 100. FIGS. 5 to 8 illustrate a growth process of the single crystal GaN layer according to an increase of a deposition time. The single crystal GaN layer 140a, which is grown around the nano-rod (see reference numeral 131 of FIG. 4) of the seed layer formed on the uneven convex portion 111 of the sapphire substrate 100 and is separated in an uneven shape is superiorly grown in a lateral direction than a vertical direction at an initial growth as shown in FIG. 5. Then, as time passed, the concave portion is filled to connect the separated single crystal GaN layers 140a to each other. Therefore, the surface of the sapphire substrate 100 is planarized as shown in FIG. 8. Through the planarization process, the voids 150 are formed on the uneven concave portion 112 as shown in FIG. 5. As the planarization process proceeds, the nano-rod 132 is grown on the end of the acicular structure formed on the uneven concave portion 112 of the sapphire substrate 100 as shown in FIG. 6. Also, the nano-rod 132 serves as the seed layer to reduce a stepped portion of the uneven structure of the sapphire substrate 100, i.e., a height difference between the convex portion 111 and the concave portion 112 through the successive planarization process. Thus, the nano-rod 132 improves a surface characteristic, i.e., a mirror surface characteristic and maintains the voids 150.

Characteristics of the semiconductor substrate in accordance with an exemplary embodiment will be described with reference to an experimental example and a comparative example. According to the experimental example, the uneven structure is formed on the sapphire substrate according to the above-described manufacturing processes. Then, the AlN buffer layer having a nano structure is formed on the uneven structure, and the seed layer having the nano-rod shape is formed. Thereafter, the single crystal GaN layer is grown to a thickness of approximately 10 μm to approximately 18 μm for approximately 10 minutes. On the other hand, according to the comparative example, the AlN buffer layer is directly formed on the sapphire substrate, and then, the single crystal GaN layer is grown to a thickness of approximately 10 μm to approximately 18 μm.

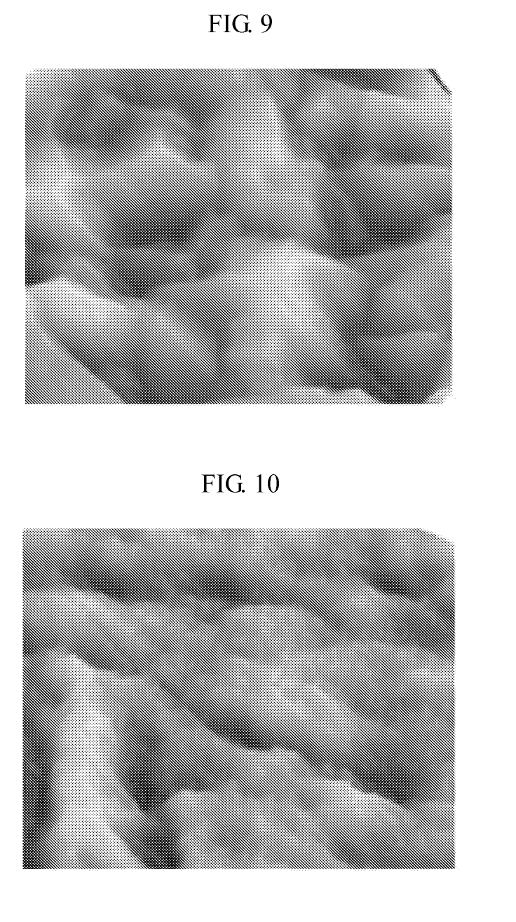

FIG. 9 is an atomic force microscope (AFM) photograph of a single crystal GaN layer in accordance with a comparative example, and FIG. 10 is an AFM photograph of a single crystal GaN layer in accordance with an experimental example.

Referring to FIGS. 9 and 10, the single crystal GaN layer according to the experimental example has a smoother surface as shown through the AFM photograph. When an actual surface roughness is measured, the single crystal GaN layer according to the comparative example has a surface roughness Ra of approximately 2,218 Å. On the other hand, the single crystal GaN layer according to the experimental example has a surface roughness Ra of approximately 5 Å. As a result, it is seen that the surface roughness characteristic is significantly improved.

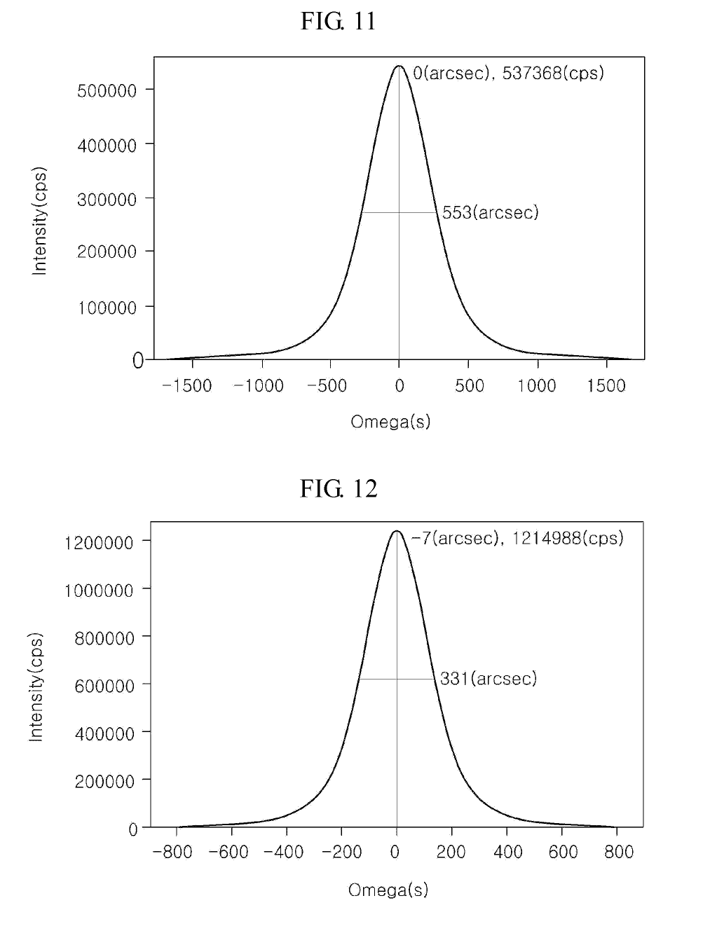

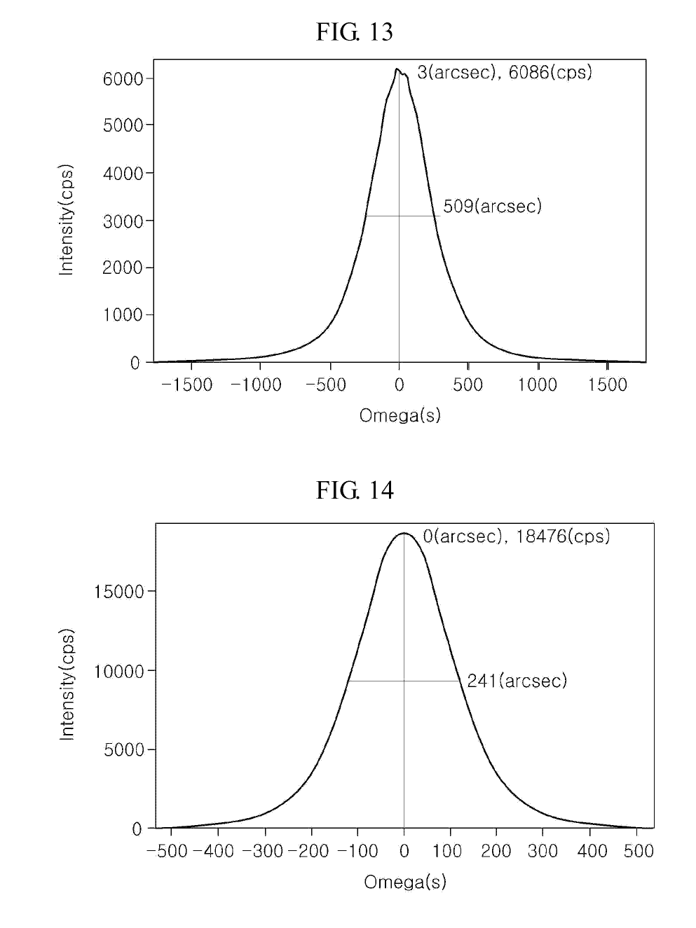

FIG. 11 is a rocking curve graph illustrating a (002) plane of the single crystal GaN layer in accordance with a comparative example, and FIG. 12 is a rocking curve graph illustrating a (002) plane of the single crystal GaN layer in accordance with an experimental example. FIG. 13 is a rocking curve graph illustrating a (102) plane of the single crystal GaN layer in accordance with a comparative example, and FIG. 14 is a rocking curve graph illustrating a (102) plane of the single crystal GaN layer in accordance with an experimental example.

Referring to FIG. 11, a (002) plane of the single crystal GaN layer according to the comparative example has a full pitch at half maximum (FPHM) of approximately 553 arcsec. On the other hand, referring to FIG. 12, a (002) plane of the single crystal GaN layer according to the experimental example has a FPHM of approximately 331 arcsec. As a result, it is seen that crystallinity of the single crystal GaN layer is improved by approximately 60%. Referring to FIG. 13, a (102) plane of the single crystal GaN layer according to the comparative example has a FPHM of approximately 509 arcsec. On the other hand, referring to FIG. 14, a (102) plane of the single crystal GaN layer according to the experimental example has a FPHM of approximately 241 arcsec. As a result, it is seen that crystallinity of the single crystal GaN layer is improved by approximately 47%.

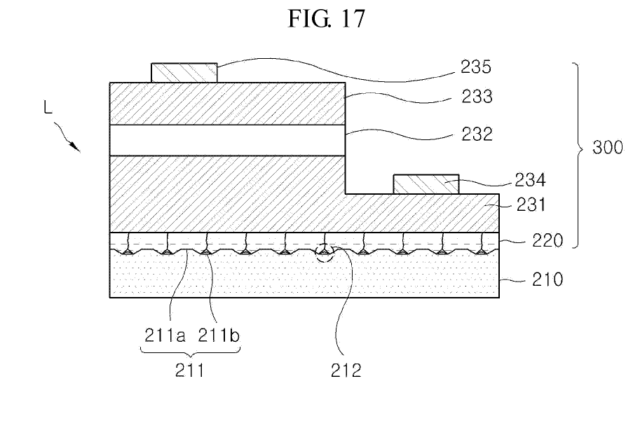

FIG. 16 is a graph illustrating warpage characteristics of a semiconductor substrate including the single crystal GaN layer in accordance with an experimental example, and FIG. 17 is a sectional view of a semiconductor device including a semiconductor substrate in accordance with an exemplary embodiment.

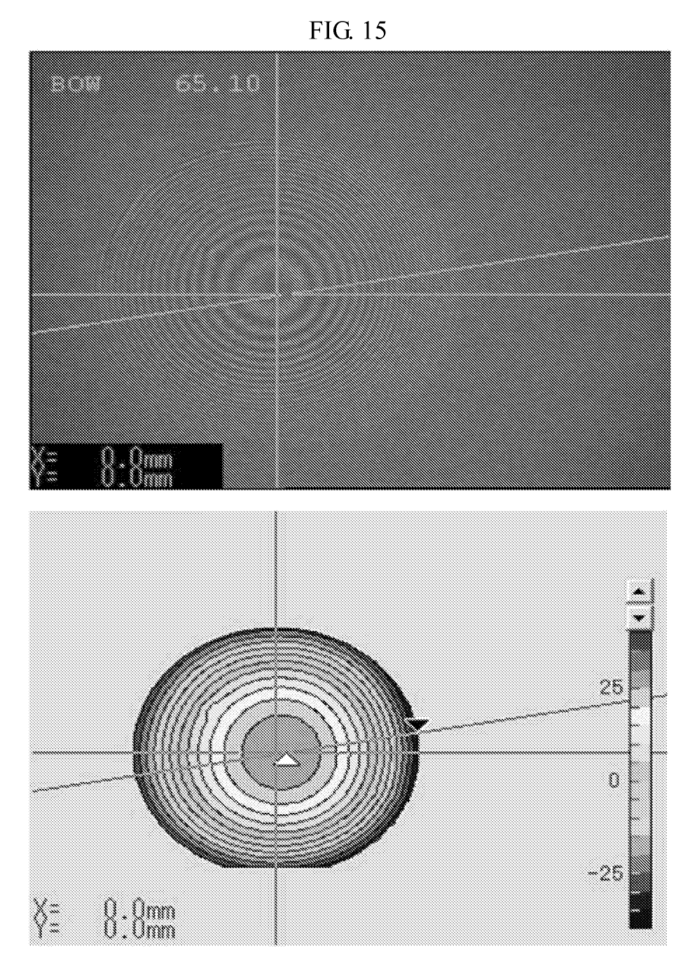

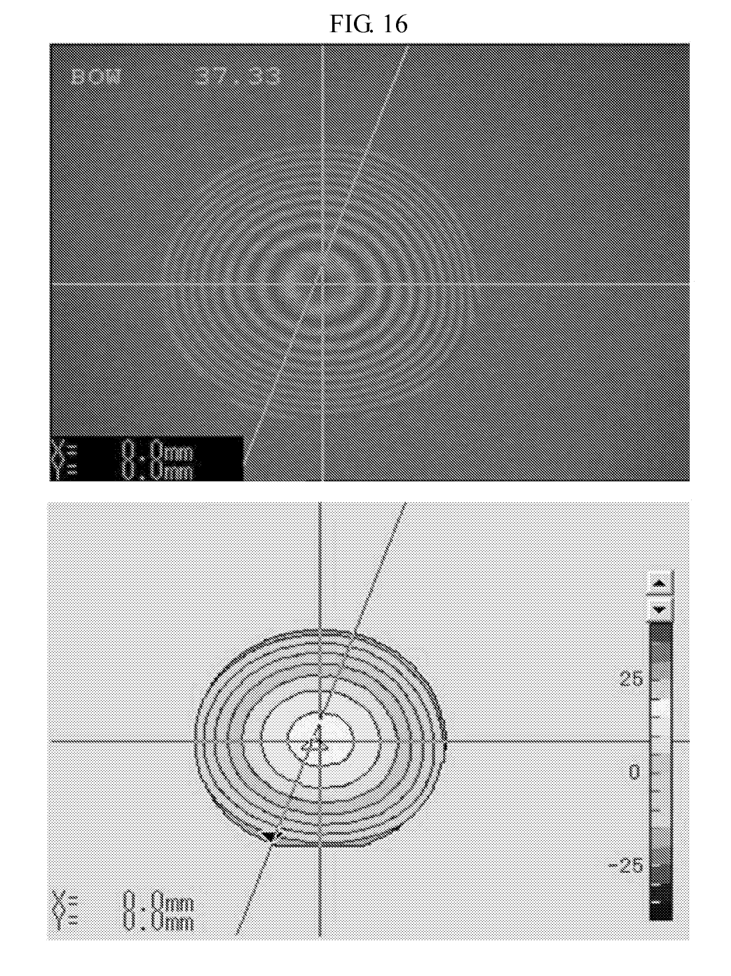

Referring to FIG. 15, a semiconductor substrate including the single crystal GaN layer according to the comparative example has a bow of approximately 65.10 μm. On the other hand, referring to FIG. 16, a semiconductor substrate including the single crystal GaN layer according to the experimental example has a bow of approximately 37.33 μm. As a result, it is seen that the semiconductor substrate according to the experimental example has a warpage characteristic less (by approximately 57%) than that of the semiconductor substrate according to the comparative example.

Thus, in the semiconductor substrate in accordance with an exemplary embodiment, since the acicular structure formed on the uneven structure of the substrate forms voids on an interface between the substrate and the GaN layer to relax the stress due to the lattice mismatch and intercepts propagation of a breakdown potential, the warpage characteristic of the grown single crystal GaN layer is reduced, as well as, the crystallinity is improved. Also, the single crystal GaN initially grown in a shape similar to that of the uneven structure of the substrate is connected to each other to planarize the surface of the substrate from a three-dimensional structure to a two-dimensional structure. Also, the nano-rod protrudes from the concave portion of the uneven structure to further planarize the surface of the substrate. Therefore, the surface roughness may be reduced.

Although a case in which the widely used single crystal GaN layer of semiconductor compound layers is formed to manufacture the semiconductor substrate is described in the current embodiment as an example, as its usage purpose, at least one of various semiconductor compound layers, e.g., AlN, InN, AlGaN, and InGaN layers instead of the above-described single crystal GaN layer may be formed to manufacture the semiconductor substrate. In this case, experimental results similar to those of the above-described experimental example may be obtained.

The semiconductor substrate in accordance with an exemplary embodiment may be used for manufacturing various semiconductor devices. Hereinafter, a semiconductor device in which various electronic devices are disposed on the above-described semiconductor device will be described as an example of such possibility.

FIG. 17 is a sectional view of a semiconductor device including a semiconductor substrate in accordance with an exemplary embodiment.

Referring to FIG. 17, the semiconductor device includes a substrate 210 having an uneven structure 211 constituted by a convex portion 211a and a concave portion 211b, a buffer layer (not shown) having an acicular structure and disposed on the uneven structure 211 of the substrate 210, and a device layer 300 including a single crystal layer 220 disposed on the buffer layer (not shown) to planarize the uneven structure. The semiconductor device may include at least one light emitting device L that converts electrical energy into optical energy on the device layer 300, and thus, the semiconductor device may be used for a light source module.

The above-described sapphire substrate is used as the substrate 210. A surface etching process is performed on the substrate to form the uneven structure 211 having a surface roughness of approximately 10 Å to approximately 300 Å.

As shown in FIG. 2 of the above-described embodiment, a nitrifying process is performed to form an AlN layer on the uneven structure of the substrate 210, and then, an etching process is formed to remove a weak portion of the layer. Here, the nitrifying process and the etching process are repeatedly performed several times to form the acicular structure (see reference 120 of FIG. 2)

The device layer 300 includes the single crystal GaN layer 220 having a thick thickness to planarize the acicular structure and the uneven structure 211 of the substrate 210. The device layer 300 includes a plurality of voids 212 formed between the GaN layer 220 and the uneven concave portion 211b of the substrate 210 in the planarization process. Since the voids 212 and the AlN buffer layer relax a stress due to a lattice mismatch between the substrate 210 and the single crystal GaN layer 220 and intercept propagation of a breakdown potential, a warpage characteristic of the grown single crystal GaN layer is reduced, as well as, crystallinity is improved.

At least one light emitting device L is disposed on the device layer 300. For example, the light emitting device includes a semiconductor layer including an n-type layer 231, an active layer 232, and a p-type layer 233, a first electrode 234 disposed on a portion region of the n-type layer 231, and a second electrode 235 disposed on a portion region of the p-type layer 233. Here, one of the n-type layer 231, the active layer 232, and the p-type layer 233, for example, the n-type layer may be formed using the lower single crystal GaN layer 220.

The n-type layer 231, the active layer 232, and the p-type layer 233 may be formed using a semiconductor thin film including at least one of Si, GaN, AlN, InGaN, AlGaN, and AlInGaN. For example, in the current embodiment, the n-type layer 231 and the p-type layer 233 may be formed using the GaN thin film, and the active layer 232 may be formed using the InGaN thin film. The n-type layer 231 is a layer for providing electrons. N-type dopant, e.g., Si, Ge, Se, Te, or C may be injected into the above-described semiconductor thin film to form the n-type layer 231. The p-type layer 233 is a layer for providing holes. P-type dopant, e.g., Mg, Zn, Be, Ca, Sr, or Ba may be injected into the semiconductor thin film to form the p-type layer 233. The active layer 232 is a layer in which the electrons provided from the n-type layer 231 and the holes provided from the p-type layer 233 are recombined to output light having a predetermined wavelength. A well layer and a barrier layer may be alternately stacked to form a multi-layered semiconductor thin film having a single quantum well structure or a multiple quantum well structure. Since a wavelength of the outputted light is converted according to a semiconductor material forming the active layer 332, an adequate semiconductor material may be selected according to a target output wavelength.

As described above, since the semiconductor device is disposed on the GaN layer having superior crystallinity and surface characteristics, a high-speed operation and stability are superior. In addition, less deformation of the substrate 210, specifically, a less warpage phenomenon may occur in the device layer formation process. Thus, substrate handling such as substrate chucking and substrate alignment may be easily performed in the subsequent process. In addition, related-art limitations such as the yield reduction and defect increase may not occur.

According to the above-described semiconductor device, although the uneven structure 211 is formed on the surface of the substrate 210, the buffer layer (not shown) having the acicular structure is formed on the uneven structure 211, and the single crystal GaN layer 220 is formed on the acicular structure to manufacture the light emitting device L, the present disclosure is not limited thereto. For example, in addition to the light emitting device L, various power devices, e.g., a transistor, a MOSFET, a schottky diode, and a photo sensor may be formed on the substrate 210.

In the semiconductor substrate in accordance with an exemplary embodiment, since the acicular structure disposed on the uneven structure of the substrate forms voids on the interface between the substrate and the single crystal GaN layer to relax the stress due to the lattice mismatch and intercept the propagation of the breakdown potential, the warpage characteristic of the grown single crystal GaN layer may be reduced, as well as, the crystallinity may be improved.

Also, in the semiconductor substrate in accordance with an exemplary embodiment, the single crystal GaN initially grown in a shape similar to that of the uneven structure of the substrate is connected to each other to planarize the surface of the substrate from a three-dimensional structure to a two-dimensional structure.

Also, in the semiconductor substrate in accordance with an exemplary embodiment, the nano-rod protrudes from the concave portion of the uneven structure to further planarize the surface of the substrate, thereby reducing the surface roughness. Therefore, the superior mirror surface characteristic may be provided.

Also, in the semiconductor substrate in accordance with an exemplary embodiment, since a less warpage phenomenon of the substrate occurs in the subsequent process even though the device layer has relatively thick thickness when the next device is manufactured, the substrate handling such as the substrate chucking and the substrate alignment may be easily performed. Therefore, a process for manufacturing the next device, e.g., the photo process and the etching process may be smoothly performed to minimize the product defects or proportion defective.

Although the substrate for the semiconductor device and the method for manufacturing the same have been described with reference to the specific embodiments, they are not limited thereto. Therefore, it will be readily understood by those skilled in the art that various modifications and changes can be made thereto without departing from the spirit and scope of the present invention defined by the appended claims.

What is claimed is:

1. A semiconductor substrate comprising:
an uneven structure formed on a surface of a substrate;
a buffer layer disposed on the uneven structure, the buffer layer having an acicular structure;
a compound semiconductor layer disposed on the buffer layer to planarize the uneven structure; and
a plurality of voids defined between the substrate and the compound semiconductor layer.

2. The semiconductor substrate of claim 1, wherein the uneven structure has a surface roughness of approximately 10 Å to approximately 300 Å.

3. The semiconductor substrate of claim 1, wherein the voids are defined between a concave portion of the uneven structure and the compound semiconductor layer.

4. The semiconductor substrate of claim 3, wherein the concave portion has a shape corresponding to a crystal shape of the substrate.

5. The semiconductor substrate of claim 1, wherein the substrate comprises one of a sapphire substrate, a silicon carbide substrate, an aluminum nitride substrate, and a zinc oxide substrate.

6. The semiconductor substrate of claim 1, wherein the compound semiconductor layer is formed of one of GaN, AlN, InN, AlGaN, and InGaN.

7. A method for manufacturing a semiconductor substrate, the method comprising:
etching a substrate surface to form an uneven structure having a shape corresponding to a crystal shape of the substrate;
forming a buffer layer having an acicular structure on the uneven structure; and
forming a compound semiconductor layer on the buffer layer to planarize the uneven structure.

8. The method of claim 7, wherein the etching of the substrate surface comprises increasing a pH value of slurry in a chemical mechanical polishing (CMP) process for polishing the substrate surface.

9. The method of claim 7, wherein the etching of the substrate surface comprises introducing HCl gas in a state where the substrate is heated.

10. The method of claim 7, wherein the etching of the substrate surface comprises immersing the substrate in KOH molten salt.

11. The method of claim 7, wherein the forming of the buffer layer comprises:
nitriding the substrate to form the buffer layer on the substrate; and
removing weak portions of the buffer layer by etching,
wherein the above steps are repeatedly performed.

12. The method of claim 7, wherein the substrate comprises one of a sapphire substrate, a silicon carbide substrate, an aluminum nitride substrate, and a zinc oxide substrate.

13. The method of claim 7, wherein the compound semiconductor layer is formed of one of GaN, AlN, InN, AlGaN, and InGaN.
